(19) United States
(12) Patent Application Publication
(10) Pub. No.: US 2020/0051765 A1
(43) Pub. Date: Feb. 13, 2020

(54) ELECTRIC APPARATUS

(71) Applicants: AUTONETWORKS TECHNOLOGIES, LTD., Mie (JP); SUMITOMO WIRING SYSTEMS, LTD., Mie (JP); SUMITOMO ELECTRIC INDUSTRIES, LTD., Osaka (JP)

(72) Inventors: Hiroomi HIRAMITSU, Mie (JP); Tomotaka KUROZU, Mie (JP); Hiroki HIRAI, Mie (JP); Makoto HIGASHIKOZONO, Mie (JP); Hideyuki KUBOKI, Mie (JP); Masato TSUTSUKI, Mie (JP)

(73) Assignees: AUTONETWORKS TECHNOLOGIES, LTD., Mie (JP); SUMITOMO WIRING SYSTEMS, LTD., Mie (JP); SUMITOMO ELECTRIC INDUSTRIES, LTD., Osaka (JP)

(21) Appl. No.: 15/999,059

(22) PCT Filed: Jan. 31, 2017
(86) PCT No.: PCT/JP2017/003318

§ 371 Date: Aug. 17, 2018

(30) Foreign Application Priority Data
Feb. 18, 2016 (JP) 2016-028643

(51) Int. Cl. H01H 45/12; H02G 3/14; H02G 3/16; H05K 7/20

(52) U.S. Cl. CPC H01H 45/12; H05K 7/20263; H02G 3/16; H02G 3/14

(57) ABSTRACT

A relay is provided with a housing, a coil arranged inside the housing, a fixed terminal, and a movable member. The housing is filled with an insulating liquid refrigerant, and the coil and the movable member are immersed in the liquid refrigerant, and at least a fixed contact of the fixed terminal is immersed in the liquid refrigerant. Heat generated in the coil, the movable member, and the fixed terminal is cooled by the liquid refrigerant, and thus the efficiency of cooling the relay is improved.

### TECHNICAL FIELD

The technology disclosed in the present description relates to an electric apparatus.

### BACKGROUND ART

In vehicles such as electric cars or hybrid cars, a battery module is installed as a power source. The battery module is provided with a plurality of electric cells, and supplies electric power to loads such as a motor. An electric apparatus for causing an electric current to flow to the loads or interrupting the current flow is connected to the battery module. The electric apparatus disclosed in JP 2011-88598A is known as such an electric apparatus.

### CITATION LIST

### Patent Documents

Patent Document 1: JP 2011-88598A

### SUMMARY OF INVENTION

### Technical Problem

Recently, in electric cars or hybrid cars, it is required that a relatively large current flows. The larger the current value is, the greater the amount of heat that is generated in the electric apparatus.

To reduce the amount of heat generation, it is conceivable to reduce the electric resistance value of conductive members provided in the electric apparatus. To reduce the resistance value of the conductive member, it is conceivable to use conductive members having a large cross-sectional area. However, simply using conductive members having a large cross-sectional area will result in an increase in the overall size of the electric apparatus, and thus is unrealistic. Accordingly, there is a demand to efficiently cool the electric apparatus when a current flows therethrough.

The technology disclosed in the present description was made in view of the above-described circumstances, and it is an object thereof to improve the efficiency of cooling an electric apparatus.

### Solution to Problem

The technology disclosed in the present description relates to an electric apparatus including: a housing; and a conductive member arranged inside the housing, wherein the housing is filled with an insulating liquid refrigerant, and at least part of the conductive member is immersed in the liquid refrigerant.

According to the above-described configuration, heat generated in the conductive member when a current flows therethrough is transferred to the liquid refrigerant in which the conductive member is immersed. Accordingly, the conductive member can be efficiently cooled, and this makes it possible to efficiently cool the electric apparatus in which the conductive member is arranged.

The embodiments of the technology disclosed in the present description include the following preferred aspects.

Preferably, the conductive member includes a busbar.

According to the above-described configuration, it is possible to efficiently cool the busbar through which a relatively large current is caused to flow.

Preferably, the conductive member includes a coil.

According to the above-described configuration, heat generated from the coil while a current flows through the coil can be efficiently transferred to the liquid refrigerant. Therefore, it is possible to efficiently cool the electric apparatus that includes the coil.

Preferably, the conductive member includes a resistor.

According to the above-described configuration, it is possible to efficiently cool the resistor that is likely to generate heat when a current flows therethrough.

Preferably, the housing has a heat dissipation member made of metal, and the conductive member is in contact with the heat dissipation member in a heat transferring manner.

According to the above-described configuration, heat generated in the conductive member when a current flows therethrough is transferred to the heat dissipation member, and is dissipated from the heat dissipation member to the outside of the housing. Accordingly, it is possible to further improve the efficiency of cooling the electric apparatus.

Preferably, the conductive member is arranged on a distribution board made of an insulating material, and the distribution board is attached to the heat dissipation member.

According to the above-described configuration, heat generated in the conductive member is transferred from the distribution board to the heat dissipation member, and is dissipated to the outside of the housing. At this time, the conductive member and the heat dissipation member are insulated from each other by the distribution board, and thus it is possible to efficiently cool the conductive member with the conductive member and the heat dissipation member electrically insulated from each other.

Preferably, the housing has an inlet via which the liquid refrigerant flows into the housing, and an outlet from which the liquid refrigerant flows to the outside of the housing.

According to the above-described configuration, it is possible to cause the liquid refrigerant that has a relatively low temperature to flow into the housing via the inlet, and cause the liquid refrigerant that has an increased temperature as a result of absorbing heat of the conductive member to flow from the outlet to the outside of the housing. Accordingly, it is possible to keep the temperature gradient between the conductive member and the liquid refrigerant, thus making it possible to improve the efficiency of cooling the electric apparatus.

### Advantageous Effects of Invention

According to the technology disclosed in the present description, it is possible to improve the efficiency of cooling an electric apparatus.

### BRIEF DESCRIPTION OF DRAWINGS

FIG. 1 is a cross-sectional view of a relay according to Embodiment 1.

FIG. 2 is a perspective view illustrating the relay.

FIG. 3 is an exploded perspective view illustrating the relay.

FIG. 4 is a cross-sectional view of a relay according to a modification of Embodiment 1.

FIG. 5 is a perspective view illustrating an electric junction box according to Embodiment 2.

FIG. 6 is a plan view illustrating the electric junction box.

FIG. 7 is a cross-sectional view taken along a line VII-VII in FIG. 6.

FIG. 8 is an exploded perspective view illustrating the electric junction box.

FIG. 9 is a plan view illustrating a circuit assembly.

FIG. 10 is a cross-sectional view of an electric junction box according to a modification of Embodiment 2.

### DESCRIPTION OF EMBODIMENTS

### Embodiment 1

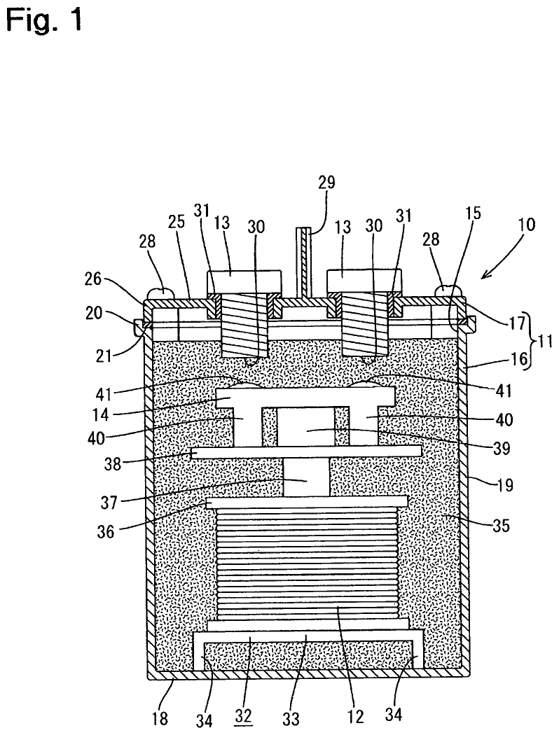

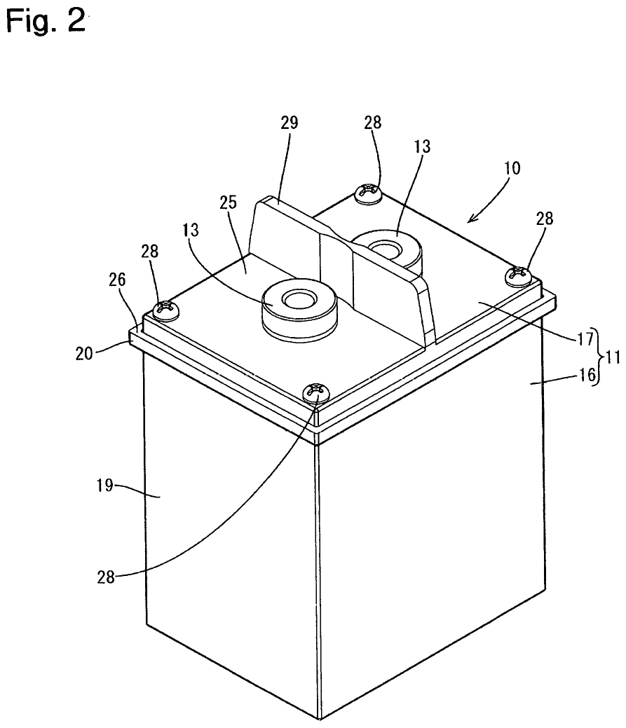

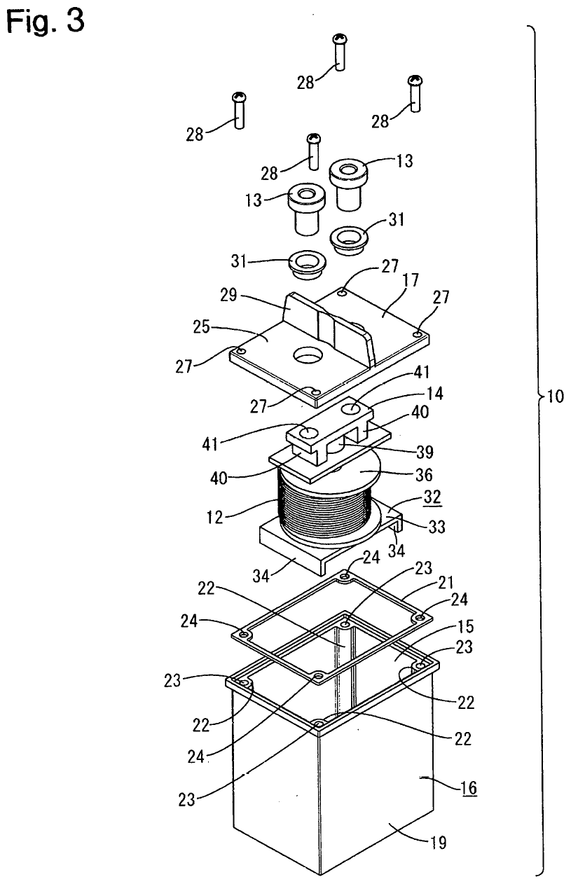

Embodiment 1 of the technology disclosed in the present description will be described with reference to FIGS. 1 to 3. A relay 10 (an example of an electric apparatus) according to the present embodiment is provided with: a housing 11 in the shape of a substantially rectangular parallelepiped; a coil 12 (an example of a conductive member) accommodated in the housing 11; fixed terminals 13 (an example of the conductive member), and a movable member 14 (an example of the conductive member) capable of making contact with the fixed terminals 13. Note that the following description will be given assuming that, using FIG. 1 as a standard, “upper” refers to the upper side in FIG. 1, and “lower” refers to the lower side in FIG. 1. Furthermore, using FIG. 1 as a standard, “right” refers to the right in FIG. 1, and “left” refers to the left in FIG. 1.

### Housing 11

The housing 11 is provided with: a case 16 with an opening 15 that opens upward; and an upper cover 17 that is fitted to the opening 15 of the case 16 and closes the opening 15. The opening 15 of the case 16 is substantially rectangular when viewed from above. The upper cover 17 conforms to the shape of the opening 15, and has an external shape slightly larger than that of the opening 15.

The case 16 may be made of metal or an insulating synthetic resin. The case 16 has a bottom wall 18, and four side walls 19, which extend upward from the side edges of the bottom wall 18. On the upper edges of the side walls 19, flange portions 20 are provided that protrude outward in the thickness direction of the side walls 19 and are bent upward. The flange portions 20 are designed such that a gasket 21 in a rectangular frame shape when viewed from above is fitted thereto. The gasket 21 is preferably made of an elastic synthetic resin, namely, rubber.

The bottom wall 18 of the case 16 has, at four corners thereof, column portions 22 that are formed extending from the lower end of the respective side walls 19 to the upper end. The column portions 22 protrude inward from the four corners. Each column portion 22 has, at the upper end thereof, a screw hole 23 extending downward. Furthermore, the gasket 21 has through holes 24 penetrating therethrough in the vertical direction, at positions that correspond to the screw holes 23 of the column portions 22 in a state in which the gasket 21 is fitted to the flange portions 20.

The upper cover 17 is made of an insulating synthetic resin. The upper cover 17 has an upper wall 25, and side walls 26 extending downward from the edges of the upper wall 25. Its configuration is such that, in a state in which the upper cover 17 is attached to the case 16, the lower end portions of the side walls 26 of the upper cover 17 abut against the gasket 21 from above. Therefore, the gasket 21 is interposed between the lower ends of the side walls 26 of the upper cover 17 and the flange portions 20 of the side walls 19 of the case 16. Accordingly, the case 16 and the upper cover 17 are sealed liquid-tightly.

The upper wall 25 of the upper cover 17 has, at four corners thereof, through holes 27 penetrating therethrough in the vertical direction. Screws 28 are respectively inserted into the through holes 27. While passing through the through holes 27 of the upper cover 17 and the through holes 24 of the gasket 21, the screws 28 are screwed into the screw holes 23 of the column portions 22 of the case 16. Accordingly, the upper cover 17 is fixed to the case 16 with the screws 28.

A partition wall 29 protruding upward is formed at a central position, in the left-right direction, of the upper wall 25 of the upper cover 17. To the right and left sides of the partition wall 29, fixed terminals 13 are respectively arranged penetrating the upper wall 25 of the upper cover 17. As a result of the fixed terminals 13 being separated from each other by the partition wall 29, a short-circuit between the fixed terminals 13 can be prevented. The end portions of the fixed terminals 13 that are located inside the housing 11 serve as fixed contacts 30.

A gasket 31 made of an elastic synthetic resin is interposed between each fixed terminal 13 and the upper cover 17. The gaskets 31 are preferably made of rubber. The gaskets 31 are in intimate contact with both the fixed terminals 13 and the upper cover 17, so that the fixed terminals 13 and the upper cover 17 are sealed liquid-tightly.

### Coil 12

A pedestal member 32 is arranged on the bottom wall 18 of the case 16. The pedestal member 32 has a top panel 33 and leg portions 34. A region below the top panel 33 is a space into which a later-described liquid refrigerant 35 can flow.

The coil 12 is placed on the top panel 33 of the pedestal member 32. The coil 12 is wound around a core 36. The coil 12 has a known configuration in which an insulation-coated electric wire is wound. The core 36 has a shape extending in the vertical direction. The core 36 is made of a magnetic material, and any magnetic material such as iron or an iron alloy, for example, may be used as the core 36 as needed.

A protruding shaft 37 protrudes upward from the upper end portion of the core 36. A magnetic member 38 made of a magnetic material is fixed to the upper end portion of the protruding shaft 37. The magnetic member 38 is plate-shaped, extending in the left-right direction.

The movable member 14 is arranged on the upper surface of the magnetic member 38. The movable member 14 is conductive, and is made of a material that can be attracted to the magnetic member 38 due to a magnetic force. Any material such as iron or an iron alloy may be appropriately selected for the metal of which the movable member 14 is made, as needed.

The movable member 14 is plate-shaped, extending substantially in the left-right direction. Two leg portions 40 protruding downward are respectively formed at positions close to the left and right end portions of the movable member 14. The portions of the movable member 14 that make contact with the fixed contacts 30 serve as moving contacts 41. The moving contacts 41 are formed at positions below the fixed contacts 30. The moving contacts 41 protrude upward in the shape of a curved surface from the upper surface of the movable member 14.

A biasing portion 39 extending in the vertical direction is arranged between the two leg portions 40, and between the movable member 14 and the magnetic member 38. The biasing portion 39 internally houses a spring that biases the movable member 14 upward, although the spring is not shown in detail. Due to the elastic force of the spring, the movable member 14 is biased upward to bring the moving contacts 41 into contact with the fixed contacts 30. Note that any spring such as a coil spring, a spiral spring, or a plate spring may be selected appropriately for the spring.

Note that when a current is caused to flow through the coil 12, the movable member 14 is attracted to the magnetic member 38 due to a magnetic force generated in the coil 12 and the core 36. As a result, the electric connection between the fixed contacts 30 and the moving contacts 41 is disconnected.

### Liquid Refrigerant 35

As shown in FIG. 1, the housing 11 is filled with the insulating liquid refrigerant 35. In FIG. 1, the liquid refrigerant 35 is hatched. As the liquid refrigerant 35, for example, one or more refrigerants selected from a group constituted by perfluorocarbon, hydrofluoroether, hydrofluoroketone, and fluorine inert fluid, oil such as silicone oil or paraffinum liquidum, and a hydrocarbon-based refrigerant may be used.

The amount of the liquid refrigerant 35 is such that preferably at least part of the coil 12 is immersed in the liquid refrigerant 35, and more preferably the entire coil 12 is immersed in the liquid refrigerant 35. Furthermore, it is particularly preferable that in a state in which the fixed contacts 30 and the moving contacts 41 are in contact with each other, the fixed contacts 30 and the moving contacts 41 be immersed in the liquid refrigerant 35. Furthermore, it is also possible that the liquid refrigerant 35 fills up to the upper end portion of the case 16.

### Assembling Process for Assembling Relay 10

The following will describe an example of a process for assembling the relay 10 according to the present embodiment. Note that the process for assembling the relay 10 is not limited to the description below.

First, the pedestal member 32 is placed on the bottom wall 18 of the case 16. The component obtained by winding the coil 12 around the core 36 and mounting the magnetic member 38 and the movable member 14 on the coil 12 is placed on the pedestal member 32.

Then, the liquid refrigerant 35 is injected into the case 16 from the opening 15 of the case 16. After a predetermined amount of liquid refrigerant 35 has been injected, the gasket 21 is fitted to the flange portions 20 of the case 16. Note that the gasket 21 may also be fitted to the flange portions 20 at any point in time before the upper cover 17 is attached.

On the other hand, the fixed terminals 13 are mounted on the upper cover 17 via the gaskets 21. The upper cover 17 in which the fixed terminals 13 are mounted, and the case 16 are fixed to each other using the screws 28. The screws 28 are inserted through the through holes 27 of the upper cover 17 and the through holes 24 of the gasket 21, and are screwed into the screw holes 23 formed in the column portions 22 of the case 16. Accordingly, the upper cover 17 and the case 16 are fixed to each other liquid-tightly. With this, the relay 10 is complete.

### Functions and Effects of Embodiment

The following will describe functions and effects of the present embodiment. The relay 10 according to the present embodiment is provided with: the housing 11; the coil 12 arranged inside the housing 11; the fixed terminals 13; and the movable member 14, and the housing 11 is filled with the insulating liquid refrigerant 35. The coil 12 and the movable member 14 are immersed in the liquid refrigerant 35, and at least the fixed contacts 30 of the fixed terminals 13 are immersed in the liquid refrigerant 35.

According to the above-described configuration, heat generated in the coil 12, the fixed terminals 13 and the movable member 14 when a current flows therethrough is transferred to the liquid refrigerant 35 that is in contact with the coil 12, the fixed terminals 13 and the movable member 14. Accordingly, it is possible to efficiently cool the coil 12, the fixed terminals 13 and the movable member 14. As a result, the relay 10 in which the coil 12, the fixed terminals 13 and the movable member 14 are arranged can be cooled efficiently. Accordingly, it is possible to suppress an increase in the temperature of the relay 10 without increasing the size of the relay 10.

Furthermore, the relay 10 according to the present embodiment includes the coil 12.

According to the foregoing configuration, heat generated from the coil 12 while a current flows through the coil 12 can be efficiently transferred to the liquid refrigerant 35. Therefore, it is possible to efficiently cool the relay 10 that includes the coil 12.

According to the present embodiment, the current continues to flow through the coil 12 during a period in which a current flow between the two fixed terminals 13 is interrupted. Accordingly, the longer the period in which the current flow between the fixed terminals 13 is interrupted is, the larger the amount of heat generation from the coil 12 becomes. Even in such a case, heat generated in the coil 12 is transferred to the liquid refrigerant 35, and thus it is possible to efficiently cool the coil 12.

### Modification of Embodiment 1

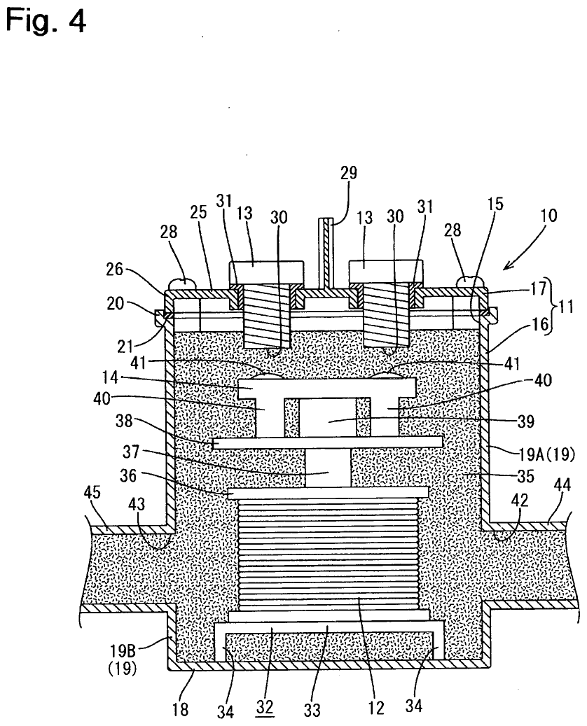

The following will describe a modification of Embodiment 1 with reference to FIG. 4. In the relay 10 according to the present modification, a side wall 19 of the case 16 has an inlet 42 via which the liquid refrigerant 35 flows into the case 16, and an outlet 43 from which the liquid refrigerant 35 flows to the outside of the case 16.

A right side wall 19A shown in FIG. 4, which is one of the side walls 19 of the case 16, has the inlet 42 penetrating the right-side wall 19A in the left-right direction, and an influx pipe 44 extends rightward from the hole edge portion of the inlet 42. The influx pipe 44 is connected to a not-shown pump, and with this pump, the liquid refrigerant 35 is caused to flow from the influx pipe 44 into the case 16 via the inlet 42.

A left side wall 19B shown in FIG. 4, which is one of the side walls 19 of the case 16, has the outlet 43 penetrating the left side wall 19B in the left-right direction. An outflux pipe 45 extends leftward from the hole edge portion of the outlet 43. The liquid refrigerant 35 in the case 16 is caused to flow from the outlet 43 to the outside of the case 16 through the outflux pipe 45.

The configurations other than the above-described ones are substantially the same as those in Embodiment 1, and thus the same reference numerals are given to the same components and redundant descriptions are omitted.

According to the present modification, the case 16 has the inlet 42 via which the liquid refrigerant 35 flows into the case 16, and the outlet 43 from which the liquid refrigerant 35 flows to the outside of the case 16.

According to the above-described configuration, it is possible to cause the liquid refrigerant 35 that has a relatively low temperature to flow into the housing 11 via the inlet 42, and cause the liquid refrigerant 35 that has an increased temperature as a result of absorbing heat of the heat coil 12, the fixed terminals 13 and the movable member 14 to flow from the outlet 43 to the outside of the housing 11. Accordingly, it is possible to keep the temperature gradient between, on the one hand, the coil 12, the fixed terminals 13 and the movable member 14, and, on the other hand, the liquid refrigerant 35, thus making it possible to improve the efficiency of cooling the relay 10.

### Embodiment 2

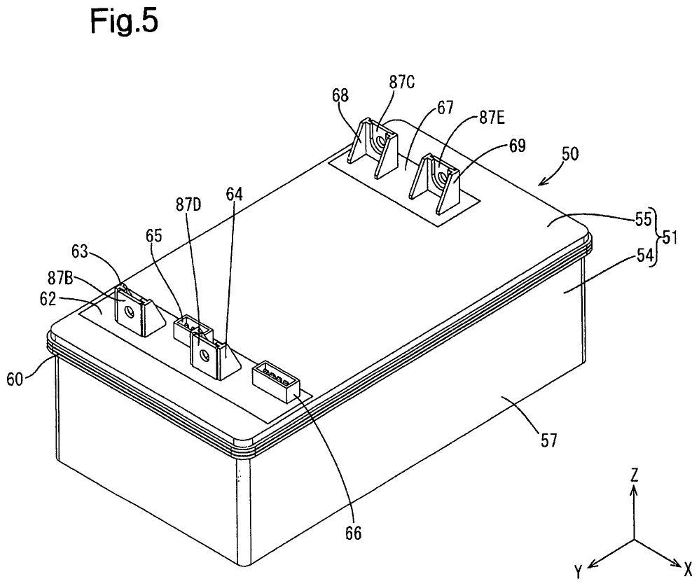

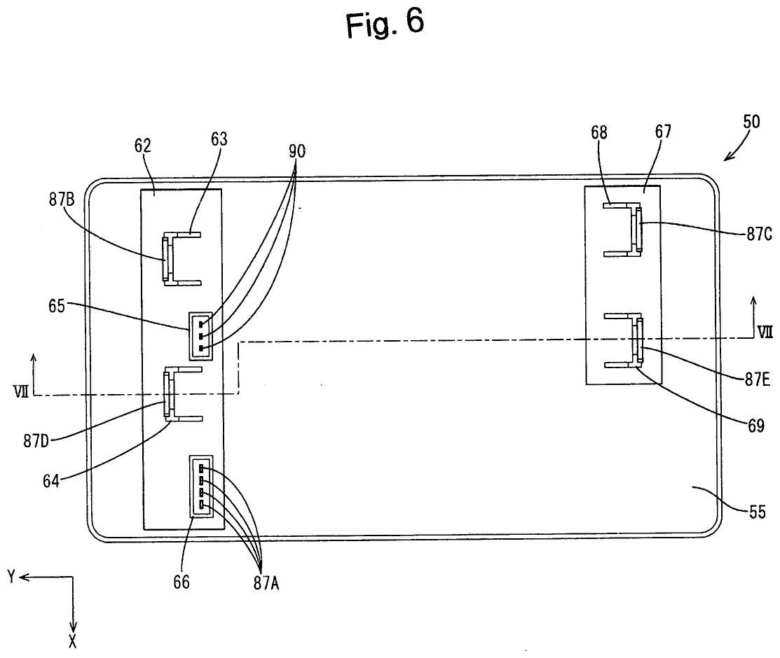

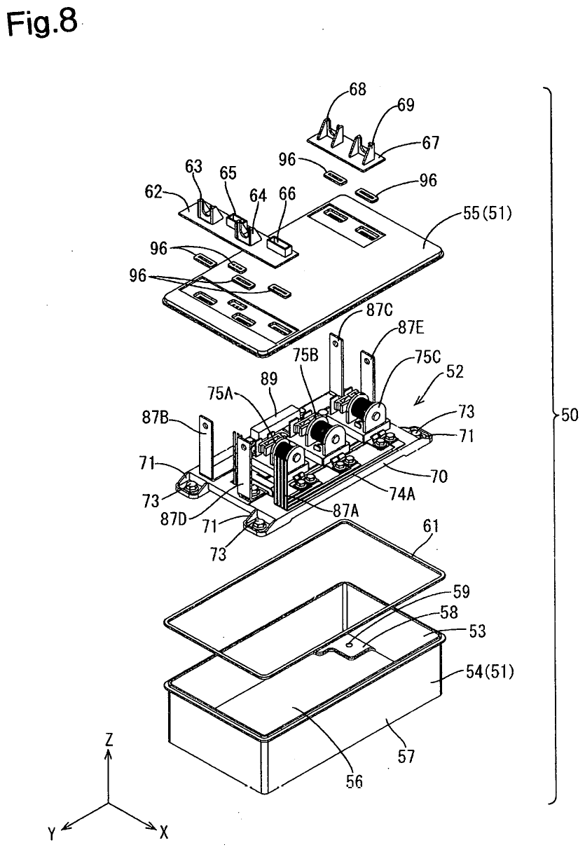

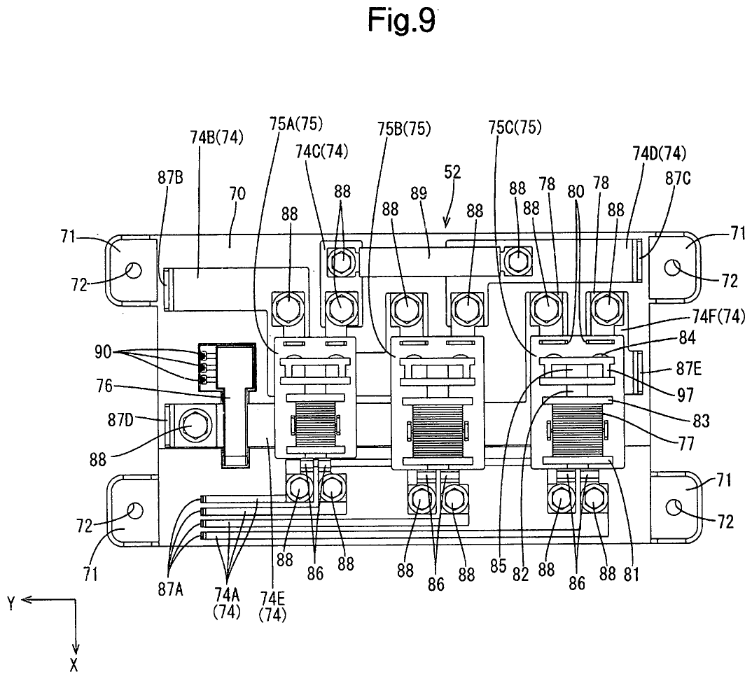

Hereinafter, Embodiment 2 of the technology disclosed in the present description will be described with reference to FIGS. 5 to 9. An electric junction box 50 (an example of the electric apparatus) according to the present embodiment is installed in a vehicle (not shown) such as an electric car or a hybrid car, and supplies electric power to loads such as a motor from a not-shown power supply, or interrupt the electric power. Note that in the following description, it is assumed that “frontward” refers to the X axis direction, “leftward” refers to the Y axis direction, and “upward” refers to the Z axis direction. Furthermore, there may be cases where reference signs are given to some of a plurality of the same members and are not given to the remaining members.

### Electric Junction Box 50

The electric junction box 50 is provided with a housing 51, and a circuit assembly 52 accommodated inside the housing 51. The electric junction box 50 has the shape of a substantially rectangular parallelepiped, as a whole.

### Housing 51

The housing 51 is provided with a metal case 54 with an opening 53 that opens upward, and an upper cover 55 that is made of a synthetic resin, and is attached to the case 54 from above to close the opening 53 of the case 54.

The case 54 includes a substantially rectangular bottom wall 56, and side walls 57 that extend from the side edges of the bottom wall 56 in the vertical direction. The portions of the side walls 57 that extend upward from the bottom wall 56 are longer than the portions that extend downward from the bottom wall 56. The bottom wall 56 of the case 54 serves as a heat dissipation member for dissipating heat generated from the circuit assembly 52 to the outside of the case 54. Any type of metal such as stainless, aluminum, or an aluminum alloy may be appropriately selected for the metal of which the case 54 is made, as needed.

Mounting pedestals 58 protruding slightly upward are formed at four corners on the upper surface of the bottom wall 56. The mounting pedestals 58 have each a screw hole 59 penetrating downward therethrough.

At positions close to the upper end portions of the side walls 57, flange portions 60 are provided that protrude outward in the thickness direction of the side walls 57. The flange portions 60 are designed such that an elastically deformable gasket 61 made of a synthetic resin is fitted thereto. The gasket 61 is preferably made of rubber.

The upper cover 55 has substantially the same plate shape as that of the opening 53 of the case 54. The upper cover 55 is made of an insulating synthetic resin. The upper cover 55 is substantially rectangular when viewed from above. As a result of the gasket 61 being interposed between the upper cover 55 and the flange portions 60 of the case 54 in a state in which the upper cover 55 is fitted to the opening 53 of the case 54, the upper cover 55 and the case 54 are sealed liquid-tightly.

A first connector block 62 that extends in a front-rear direction is arranged on the upper surface of the upper cover 55 at a position close to the left end portion thereof. The length, in the front-rear direction, of the first connector block 62 is set to be slightly shorter than the length, in the front-rear direction, of the upper cover 55. On the first connector block 62, a first positive terminal connector 63 and a first negative terminal connector 64 are provided side by side in the front-rear direction. Also, a current sensor connector 65 is provided in the vicinity of the center, in the front-rear direction, of the first connector block 62. Furthermore, a driving connector 66 is provided at a position close to the front-end portion of the first connector block 62.

Furthermore, a second connector block 67 that extends in the front-rear direction is arranged on the upper surface of the upper cover 55 at a position close to the right rear end portion thereof. The length, in the front-rear direction, of the second connector block 67 is set to be almost half of the length, in the front-rear direction, of the upper cover 55.

On the second connector block 67, a second positive terminal connector 68 and a second negative terminal connector 69 are provided side by side in the front-rear direction.

### Circuit Assembly 52

The circuit assembly 52 includes circuits formed on a distribution board 70 made of an insulating synthetic resin. The distribution board 70 is substantially rectangular when viewed from above. At four corners of the distribution board 70, four leg portions 71 protrude outward in the left-right direction and protrude downward. Each leg portion 71 has a through hole 72 penetrating therethrough in the vertical direction.

While passing through the through holes 72 formed in the leg portions 71, bolts 73 are screwed in the screw holes 59 formed in the mounting pedestals 58 of the case 54. Accordingly, the distribution board 70 is fixed to the bottom wall 56 of the case 54. As a result, the distribution board 70 and the bottom wall 56 of the case 54 are connected to each other in a heat transferring manner.

A plurality of busbars 74 (an example of the conductive member) each made of a metal plate material, a plurality of (three, in the present embodiment) relays 75 connected to the busbars 74, and a current sensor 76 for detecting a current flowing through the busbars 74 are arranged on the upper surface of the distribution board 70.

### Relay 75

The relays 75 include a precharge relay 75A, a positive terminal main relay 75B, and a negative terminal main relay 75C in order from the left. Note that the description common to the relays 75A, 75B, and 75C will be given using a “relay 75”.

The relay 75 is provided with a coil 77 (an example of the conductive member), fixed terminals 78 (an example of the conductive member), and movable members 79 (an example of the conductive member) capable of contacting the fixed terminals 78.

Each relay 75 includes a pair of fixed terminals 78. The front-end portions of the fixed terminals 78 serve as fixed contacts 80.

The coil 77 is wound around a core 81. The coil 77 has a known configuration in which an insulation-coated electric wire is wound. The core 81 has a shape extending in the vertical direction. The core 81 is made of a magnetic material, and any magnetic material such as iron or an iron alloy, for example, may be used as needed.

A protruding shaft 82 protrudes rearward from the rear end portion of the core 81. A magnetic member 83 made of a magnetic material is fixed to the rear end portion of the protruding shaft 82. The magnetic member 83 is plate-shaped, extending in the left-right direction.

The movable member 79 is arranged on the rear surface of the magnetic member 83. The movable member 79 is conductive, and is made of a material that can be attracted to the magnetic member 83 due to a magnetic force. Any material such as iron or an iron alloy may be appropriately selected for the metal of which the movable member 79 is made, as needed.

The movable member 79 is plate-shaped, extending in the left-right direction. Two leg portions 97 protruding frontward are respectively formed at positions close to the left and right end portions of the movable member 79. The portions of the movable member 79 that make contact with the fixed contacts 80 serves as moving contacts 84. The moving contacts 84 are formed at positions before the fixed contacts 80. The moving contacts 84 protrude rearward in the shape of a curved surface from the rear surface of the movable member 79.

A biasing portion 85 extending in the front-rear direction is arranged between the two leg portions 97, and between the movable member 79 and the magnetic member 83. The biasing portion 85 internally houses a spring that biases the movable member 79 rearward, although the spring is not shown in detail. Due to the elastic force of the spring, the movable member 79 is biased rearward to bring the moving contact 84 into contact with the fixed contact 80. Note that any spring such as a coil 77 spring, a spiral spring, or a plate spring may be selected appropriately for the spring.

Note that when a current is caused to flow through the coil 77, the movable member 79 is attracted to the magnetic member 83 due to a magnetic force generated in the coil 77 and the core 81. As a result, the electric connection between the fixed contact 80 and the moving contact 84 is disconnected.

A pair of driving terminals 86 (an example of the conductive member) are connected to the coil wires of the coil 77 at positions before the coil 77.

### Busbar 74

The busbars 74 include control busbars 74A (an example of the conductive member) that are connected to the driving terminals 86 of the relays 75, and supply a current to the coils 77.

The control busbars 74A each have a relatively elongated shape. On the upper surface of a base plate portion of the distribution board 70, the multiple (four, in the present embodiment) control busbars 74A are arranged side by side at intervals in the vertical direction at positions close to the front-end portion. The control busbars 74A are connected to the driving terminals 86 of the coils 77 with bolts 88 (an example of the conductive member).

Each control busbar 74A has, in the left end portion thereof, an upward protruding portion 87A protruding upward. The upward protruding portions 87A of the control busbars 74A are arranged in the driving connector 66. The control busbars 74A are connected to a not-shown ECU (Electronic Control Unit) for controlling the operation of the relays 75.

The busbars 74 include a first positive terminal busbar 74B, a second positive terminal busbar 74C, a third positive terminal busbar 74D, a first negative terminal busbar 74E, and a second negative terminal busbar 74F, which are connected to the fixed terminals 78 of the relays 75.

The first positive terminal busbar 74B, the second positive terminal busbar 74C, the third positive terminal busbar 74D, the first negative terminal busbar 74E, and the second negative terminal busbar 74F are larger in width than the control busbars 74A, and are arranged, on the upper surface of the base plate portion of the distribution board 70, in a region behind the region in which the control busbars 74A are arranged.

The first positive terminal busbar 74B is arranged at a position close to the left rear end portion of the distribution board 70. At the left end portion of the first positive terminal busbar 74B, an upward protruding portion 87B extending in the vertical direction is attached with a bolt 88. The upper end portion of the upward protruding portion 87B is arranged in the first positive terminal connector 63. The first positive terminal busbar 74B is connected to a positive terminal of the not-shown power supply.

One of the fixed terminals 78 of the precharge relay 75A is connected to the first positive terminal busbar 74B with a bolt 88. Furthermore, one of the fixed terminals 78 of the positive terminal main relay 75B is connected to the right end portion of the first positive terminal busbar 74B with a bolt 88.

The second positive terminal busbar 74C is arranged at a position behind the precharge relay 75A on the distribution board 70. The other one of the fixed terminals 78 of the precharge relay 75A that is not connected to the first positive terminal busbar 74B is connected to the second positive terminal busbar 74C with a bolt 88. A precharge resistor 89 (an example of the conductive member) is connected to the rear end portion of the second positive terminal busbar 74C with a bolt 88.

The third positive terminal busbar 74D is arranged at a position to the right of the second positive terminal busbar 74C on the distribution board 70, and is arranged behind the positive terminal main relay 75B and the negative terminal main relay 75C. The precharge resistor 89 (an example of a resistor) is connected to the left end portion of the third positive terminal busbar 74D with a bolt 88. Furthermore, the other one of the fixed terminals 78 of the positive terminal main relay 75B that is not connected to the first positive terminal busbar 74B is connected to the third positive terminal busbar 74D. The right end portion of the third positive terminal busbar 74D has an upward protruding portion 87C protruding upward. The upper end portion of the upward protruding portion 87C of the third positive terminal busbar 74D is arranged in the second positive terminal connector 68. The third positive terminal busbar 74D is connected to a not-shown load.

The first negative terminal busbar 74E is arranged at a position slightly forward of the central position, in the front-rear direction, of the distribution board 70 while extending in the left-right direction. The first negative terminal busbar 74E has, in the left end portion thereof, an upward protruding portion 87D protruding upward. The upward protruding portion 87D of the first negative terminal busbar 74E is arranged in the first negative terminal connector 64. The first negative terminal busbar 74E is connected to a negative terminal of a not-shown power supply. The right end portion of the first negative terminal busbar 74E is connected to one of the fixed terminals 78 of the negative terminal main relay 75C with a bolt 88.

The second negative terminal busbar 74F is connected, with a bolt 88, to the other one of the fixed terminal 78 of the negative terminal main relay 75C that is not connected to the first negative terminal busbar 74E. The second negative terminal busbar 74F has, in the right end portion thereof, an upward protruding portion 87E protruding upward. The upward protruding portion 87E of the second negative terminal busbar 74F is arranged in the second negative terminal connector 69. The second negative terminal busbar 74F is connected to a not-shown load.

The electric junction box 50 supplies electric power from the power supply to loads in the following manner. The not-shown ECU turns on the relays 75A, 75B, and 75C in accordance with an ignition switch being turned on, and starts supplying power from the power supply to loads. At this time, the ECU first turns on the precharge relay 75A and the negative terminal main relay 75C to perform power supply via the precharge resistor 89, and then turns on the positive terminal main relay 75B. This precharge resistor 89 is configured to prevent an inrush current that rushes into the loads from the power supply.

Gaskets 96 are fitted to the upward protruding portions 87A, 87B, 87C, 87D, and 87E of the busbars 74A, 74B, 74D, 74E, and 74F. Accordingly, the upward protruding portions 87 of the busbars 74A, 74B, 74D, 74E, and 74F, and the upper cover 55 are sealed liquid-tightly.

### Current Sensor 76

The current sensor 76 is arranged on the first negative terminal busbar 74E, and is configured to detect a current caused to flow through the first negative terminal busbar 74E. The current sensor 76 has a known configuration, and includes a core (not shown) with a gap, a hall element (not shown) placed in the gap of the core, and a sensor output terminal 90 connected to the hall element. The sensor output terminals 90 are each made of an elongated metal plate material, and protrude upward. The upper end portions of the sensor output terminals 90 are arranged in the current sensor connector 65.

### Liquid Refrigerant 91

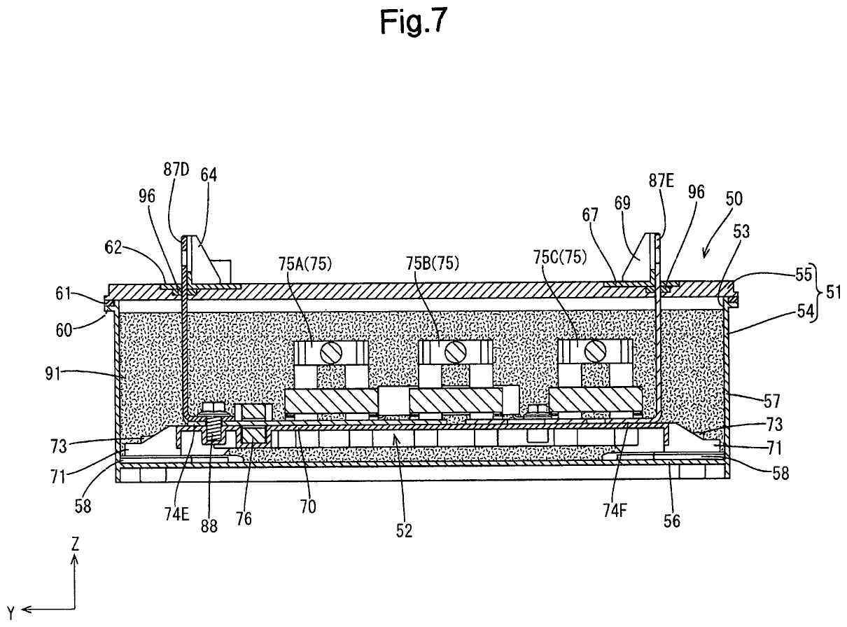

As shown in FIG. 7, the case 54 is filled with an insulating liquid refrigerant 91. The liquid refrigerant 91 is filled up to positions close to the upper end portions of the side walls 57 of the case 54. Accordingly, the relays 75, the precharge resistor 89, the coils 77, the fixed terminals 78, the movable members 79, and the second positive terminal busbar 74C are immersed in the liquid refrigerant 91.

Furthermore, when a current is caused to flow through members coupled to each other with a bolt 88, there is the risk that heat may be generated in the members coupled to each other with the bolt 88 due to contact resistance generated between the members. Accordingly, it is preferable that the bolts 88, and the members coupled to each other with the bolts 88 are immersed in the liquid refrigerant 91. The members coupled to each other with the bolts 88 include the fixed terminals 78, the driving terminals 86, the control busbar 74A, the first positive terminal busbar 74B, the second positive terminal busbar 74C, the third positive terminal busbar 74D, the upward protruding portion 87D, the first negative terminal busbar 74E, the second negative terminal busbar 74F, and the precharge resistor 89.

Since the liquid refrigerant 91 has insulating properties, the relays 75 do not require any member for covering the coils 77, the fixed terminals 78, and the movable members 79. Also, there is no need of providing an insulating wall for insulating adjacent busbars 74 from each other on the distribution board 70. Therefore, it is possible to downsize the circuit assembly 52.

Furthermore, the portion of the first positive terminal busbar 74B excluding the upper end portion of the upward protruding portion 87B, the portion of the third positive terminal busbar 74D excluding the upper end portion of the upward protruding portion 87C, the portion of the second negative terminal busbar 74F excluding the upper end portion of the upward protruding portion 87D, and the portion of the second negative terminal busbar 74F excluding the upward protruding portion 87E are immersed in the liquid refrigerant 91.

In FIG. 7, the liquid refrigerant 91 is hatched. As the liquid refrigerant 91, for example, one or more refrigerant selected from a group constituted by perfluorocarbon, hydrofluoroether, hydrofluoroketone, and fluorine inert fluid, oil such as silicone oil or paraffinum liquidum, and a hydrocarbon-based refrigerant may be used.

### Functions and Effects of Embodiment

The following will describe functions and effects of the present embodiment. The electric junction box 50 according to the present embodiment is provided with: the housing 51; and the control busbars 74A, the first positive terminal busbar 74B, the second positive terminal busbar 74C, the third positive terminal busbar 74D, the upward protruding portion 87D, the first negative terminal busbar 74E, the second negative terminal busbar 74F, the coils 77, the movable members 79, the fixed terminals 78, the driving terminal 86, the bolts 88, and the precharge resistor 89, which are disposed in the housing 51. The housing 51 is filled with the insulating liquid refrigerant 91, and at least parts of the control busbars 74A, the first positive terminal busbar 74B, the second positive terminal busbar 74C, the third positive terminal busbar 74D, the upward protruding portion 87D, the first negative terminal busbar 74E, the second negative terminal busbar 74F, the coils 77, the movable members 79, the fixed terminals 78, the driving terminals 86, the bolts 88, and the precharge resistor 89 are immersed in the liquid refrigerant.

According to the foregoing configuration, heat generated in the control busbars 74A, the first positive terminal busbar 74B, the second positive terminal busbar 74C, the third positive terminal busbar 74D, the upward protruding portion 87D, the first negative terminal busbar 74E, the second negative terminal busbar 74F, the coils 77, the movable members 79, the fixed terminals 78, the driving terminals 86, the bolts 88, and the precharge resistor 89 when a current flows therethrough is transferred to the liquid refrigerant with which they are in contact. Accordingly, it is possible to efficiently cool the control busbars 74A, the first positive terminal busbar 74B, the second positive terminal busbar 74C, the third positive terminal busbar 74D, the upward protruding portion 87D, the first negative terminal busbar 74E, the second negative terminal busbar 74F, the coils 77, the movable members 79, the fixed terminals 78, the driving terminals 86, the bolts 88, and the precharge resistor 89, thus making it possible to efficiently cool the electric junction box 50 in which they are arranged.

Because a relatively large current flows through the first positive terminal busbar 74B, the second positive terminal busbar 74C, the third positive terminal busbar 74D, the first negative terminal busbar 74E, and the second negative terminal busbar 74F, the amount of heat generation tends to increase. According to the present embodiment, it is possible to efficiently cool the first positive terminal busbar 74B, the second positive terminal busbar 74C, the third positive terminal busbar 74D, the first negative terminal busbar 74E, and the second negative terminal busbar 74F.

The electric junction box 50 according to the present embodiment includes the precharge resistor 89. A current is caused to flow through the precharge resistor 89 for a very short period. However, a relatively large current is caused to flow through the precharge resistor 89, and thus heat is generated in the precharge resistor 89. According to the present embodiment, it is possible to efficiently cool the precharge resistor 89.

Note that, even if a defect occurs in the electric junction box 50 or the ECU and a large current flows continuously through the precharge resistor 89, it is possible in the present embodiment to cool the precharge resistor 89 using the liquid refrigerant 91.

Furthermore, according to the present embodiment, the housing 51 has the metal bottom wall 56, and the conductive members arranged on the distribution board 70 are in contact with the bottom wall 56 in a heat transferring manner. Note that the conductive members according to the present embodiment include the control busbars 74A, the first positive terminal busbar 74B, the second positive terminal busbar 74C, the third positive terminal busbar 74D, the upward protruding portion 87D, the first negative terminal busbar 74E, the second negative terminal busbar 74F, the coils 77, the movable members 79, the fixed terminals 78, the driving terminals 86, the bolts 88, and the precharge resistor 89.

According to the above-described configuration, heat generated in the conductive members when a current flows therethrough is transferred to the bottom wall 56, and is dissipated from the bottom wall 56 to the outside of the housing 51. Accordingly, it is possible to further improve the efficiency of cooling the electric junction box 50.

Also, according to the present embodiment, the conductive members are arranged on the surface of the distribution board 70 made of an insulating material, and the distribution board 70 is attached to the bottom wall 56.

According to the above-described configuration, heat generated in the conductive members is transferred from the distribution board 70 to the bottom wall 56, and is dissipated to the outside of the housing 51. At this time, the conductive member and the bottom wall 56 are insulated from each other by the distribution board 70, and thus it is possible to efficiently cool the conductive members with the conductive members and the bottom wall 56 electrically insulated from each other.

### Modification of Embodiment 2

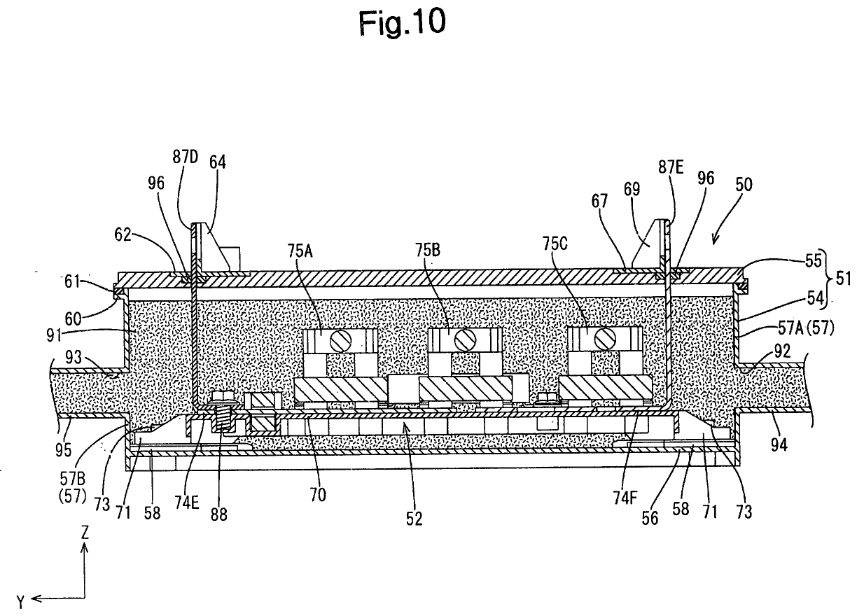

The following will describe a modification of Embodiment 2 with reference to FIG. 10. In the electric junction box 50 according to the present modification, a side wall 57 of the case 54 has an inlet 92 via which the liquid refrigerant 91 flows into the case 54, and an outlet 93 from which the liquid refrigerant 91 flows to the outside of the case 54.

A right side wall 57A shown in FIG. 10, which is one of the side walls 57 of the case 54, has the inlet 92 penetrating the right-side wall 57A in the left-right direction, and an influx pipe 94 extends rightward from the hole edge portion of the inlet 92. The influx pipe 94 is connected to a not shown pump, and with this pump, the liquid refrigerant 91 is caused to flow from the influx pipe 94 into the case 54 via the inlet 92.

A left side wall 57B shown in FIG. 10, which is one of the side walls 57 of the case 54, has the outlet 93 penetrating through the left side wall 57B in the left-right direction. An outflux pipe 95 extends leftward from the hole edge portion of the outlet 93. The liquid refrigerant 91 in the case 54 is caused to flow from the outlet 93 to the outside of the case 54 through the outflux pipe 95.

The configurations other than the above-described ones are substantially the same as those in Embodiment 2, and thus the same reference numerals are given to the same components and redundant descriptions are omitted.

According to the above-described configuration, it is possible to cause the liquid refrigerant 91 that has a relatively low temperature to flow into the housing 51 via the inlet 92, and cause the liquid refrigerant 91 that has an increased temperature as a result of absorbing heat of the conductive members to flow from the outlet 93 to the outside of the housing 51. Accordingly, it is possible to keep the temperature gradient between the conductive members and the liquid refrigerant 91, thus making it possible to improve the efficiency of cooling the electric junction box 50.

### Other Embodiments

The technology disclosed in the present description is not limited to the embodiments explained in the foregoing description with reference to the drawings, and the technical scope of the technology disclosed in the present description encompasses, for example, the following embodiments:

(1) In the embodiments, the electric junction box 50 and the relay 10 are described as an electric apparatus, but the present invention is not limited to those and the technology disclosed in the present description is applicable to any electric apparatus such as a switch box, a DC-DC converter, or an ECU.

(2) In Embodiment 2, the electric junction box 50 has a configuration in which the housing 51 houses three relays 75, but the present invention is not limited to those and a configuration is also possible in which the housing 51 houses one or two relays 75, or four or more relays 75.

(3) In Embodiment 2, the busbars 74, the coils 77, and the precharge resistor 89 are exemplified as conductive members that are immersed in the liquid refrigerant 91, but the present invention is not limited to those and any electronic components such as a capacitor, a semiconductor element, or a microcomputer may be used as the conductive member.

(4) Embodiment 2 has a configuration in which the precharge relay 75A and the precharge resistor 89 are connected to positive terminals of batteries, but the present invention is not limited to those and the precharge relay 75A and the precharge resistor 89 may also be connected to negative terminals of batteries.

(5) In Embodiment 2, the case 54 is made of metal, but the present invention is not limited to this and the case 54 may also be made of a synthetic resin.

### LIST OF REFERENCE NUMERALS

10: Relay (electric apparatus)
11: Housing
12: Coil (conductive member)
13: Fixed terminal (conductive member)
14: Movable member (conductive member)
16: Case (housing)
17: Upper cover (housing)
35: Liquid refrigerant
42: Inlet
43: Outlet
50: Electric junction box (electric apparatus)
51: Housing
54: Case (housing)
55: Upper cover (housing)
56: Bottom wall (heat dissipation member)
70: Distribution board
74A: Control busbar (conductive member)
74B: First positive terminal busbar (conductive member)
74C: Second positive terminal busbar conductive member)
74D: Third positive terminal busbar (conductive member)
74E: First negative terminal busbar (conductive member)
74F: Second negative terminal busbar (conductive member)
77: Coil (conductive member)
78: Fixed terminal (conductive member)
79: Movable member (conductive member)
87D: Upward protruding portion (conductive member)
88: Bolt (conductive member)
89: Precharge resistor (conductive member)
91: Liquid refrigerant
92: Inlet
93: Outlet

1. An electric apparatus comprising:
a housing that has a heat dissipation member made of metal; and
a conductive member arranged inside the housing,
wherein the housing is filled with an insulating liquid refrigerant,
at least part of the conductive member is immersed in the liquid refrigerant,
the conductive member is arranged on a distribution board made of an insulating material, and
the distribution board is arranged facing the heat dissipation member.

2. The electric apparatus according to claim 1,
wherein the conductive member includes a busbar.

3. The electric apparatus according to claim 1,
wherein the conductive member includes a coil.

4. The electric apparatus according to claim 1,
wherein the conductive member includes a resistor.

5. The electric apparatus according to claim 1,
wherein the conductive member is in contact with the heat dissipation member in a heat transferring manner.

6. The electric apparatus according to claim 1,
wherein the distribution board is attached to the heat dissipation member.

7. The electric apparatus according to claim 1,
wherein the housing has an inlet via which the liquid refrigerant flows into the housing, and an outlet from which the liquid refrigerant flows to the outside of the housing.
